(19) United States
(12) Patent Application Publication
(10) Pub. No.: US 2009/0078975 A1
(43) Pub. Date: Mar. 26, 2009

(54) CMOS image sensor

(75) Inventors: Byung Hoon Kim, Gyunggi-do (KR); Won Tae Choi, Gyunggi-do (KR); Boo Dong Kwak, Gyunggi-do (KR)

Correspondence Address: STAAS & HALSEY LLP, SUITE 700, 1201 NEW YORK AVENUE, N.W., WASHINGTON, DC, 20005, US

(73) Assignee: SAMSUNG ELECTRO-MECHANICS CO., LTD., Suwon (KR)

(21) Appl. No.: 12/232,681

(22) Filed: Sep. 22, 2008

(30) Foreign Application Priority Data
Sep. 21, 2007 (KR) 2007-0097024

(51) Int. Cl. H01L 31/00

(52) U.S. Cl. 257/292; 257/E31.001

(57) ABSTRACT

There is provided a CMOS image sensor including: a photodiode receiving light to generate photogenerated charges; a transmission gate unit transmitting the photogenerated charges generated by the photodiode to a first floating diffusion area, and increasing the capacitance of the first floating diffusion area; a transfer transistor transferring the photogenerated charges of the first floating diffusion area transmitted by the transmission gate unit to a second floating diffusion area; and a drive transistor converting the photogenerated charges of the second floating diffusion area into a detection voltage.

### CROSS-REFERENCE TO RELATED APPLICATIONS

This application claims the priority of Korean Patent Application No. 2007-0097024 filed on Sep. 21, 2007, in the Korean Intellectual Property Office, the disclosure of which is incorporated herein by reference.

### BACKGROUND OF THE INVENTION

1. Field of the Invention

The present invention relates to CMOS image sensors that can be applied to camera modules, and more particularly, to a CMOS image sensor that can maintain high sensitivity even at low levels of luminance by reducing thermal noise.

2. Description of the Related Art

In general, image sensors are used in a wide variety of applications ranging from household devices, such as digital cameras and cellular phones, or endoscopes used in hospitals, to telescopes of satellites traveling around the Earth.

Among these CMOS image sensors, CMOS image sensors that are manufactured using CMOS technology are devices that convert optical images into electric signals. MOS transistors are used as many as the number of pixels. Then, the MOS transistors are used to sequentially detect outputs. That is, a switching method is used in the CMOS image sensors.

In general, when compared with a CCD image sensor that is widely used in the related art, a CMOS image sensor can provide an easy driving method, allow various scanning methods, reduce product size by integrating a signal processing circuit into a single chip, reduce manufacturing costs by using compatible CMOS technology, and consume less power. Thus, CMOS image sensors are used in devices such as cellular phones, PCs, and surveillance cameras, which require low cost and low power consumption.

FIG. 1 is a configuration view illustrating a CMOS image sensor according to the related art.

According to the related art, a CMOS image sensor, shown in FIG. 1, includes a photodiode PD, a transfer transistor T-MOS, a reset transistor R-MOS, a drive transistor D-MOS, and a select transistor S-MOS. The photodiode PD receives light to generate photogenerated charges. The transfer transistor T-MOS transfers the photogenerated charges, generated by the photodiode PD, to a floating diffusion area FDA. The reset transistor R-MOS resets the floating diffusion area FDA. The drive transistor D-MOS converts the photogenerated charges of the floating diffusion area FDA into a voltage. The select transistor S-MOS is connected between the drive transistor D-MOS and the output terminal OUT, and selects a detection voltage that is output by the drive transistor D-MOS.

According to the related art, the CMOS image sensor generates reset noise caused by the operation of the reset transistor R-MOS. The generated reset noise is thermal noise that causes deterioration of the sensitivity of the CMOS image sensor.

Further, a very small amount of light is incident upon the photodiode at low levels of luminance. Therefore, if thermal noise components are greater than a signal detected at this time, the deterioration of the signal cannot be avoided.

### SUMMARY OF THE INVENTION

An aspect of the present invention provides a CMOS image sensor that can maintain high sensitivity even at low levels of luminance by reducing thermal noise.

According to an aspect of the present invention, there is provided a CMOS image sensor including: a photodiode receiving light to generate photogenerated charges; a transmission gate unit transmitting the photogenerated charges generated by the photodiode to a first floating diffusion area, and increasing the capacitance of the first floating diffusion area; a transfer transistor transferring the photogenerated charges of the first floating diffusion area transmitted by the transmission gate unit to a second floating diffusion area; and a drive transistor converting the photogenerated charges of the second floating diffusion area into a detection voltage.

The CMOS image sensor may further include a reset transistor resetting the photogenerated charges of the second floating diffusion area.

The CMOS image sensor may further include a select transistor connected between the drive transistor and an output terminal, and selecting output of the detection voltage detected by the drive transistor.

The drive transistor may be a source follower transistor having a drain connected to a power supply, a source connected to the select transistor, and a gate connected to the second floating diffusion area.

The transmission gate unit may include: an N-MOS transistor having a source connected to the photodiode, a drain connected to the transfer transistor, and a gate connected to a first gate voltage terminal; and a P-MOS transistor having a source connected to the source of the N-MOS transistor, a drain connected to the drain of the N-MOS transistor, and a gate connected to a second gate voltage terminal.

A first gate voltage may be equal to a voltage of the power supply.

The second gate voltage terminal may be connected to a ground terminal.

### BRIEF DESCRIPTION OF THE DRAWINGS

The above and other aspects, features and other advantages of the present invention will be more clearly understood from the following detailed description taken in conjunction with the accompanying drawings, in which:

FIG. 1 is a configuration view illustrating a CMOS image sensor according to the related art;

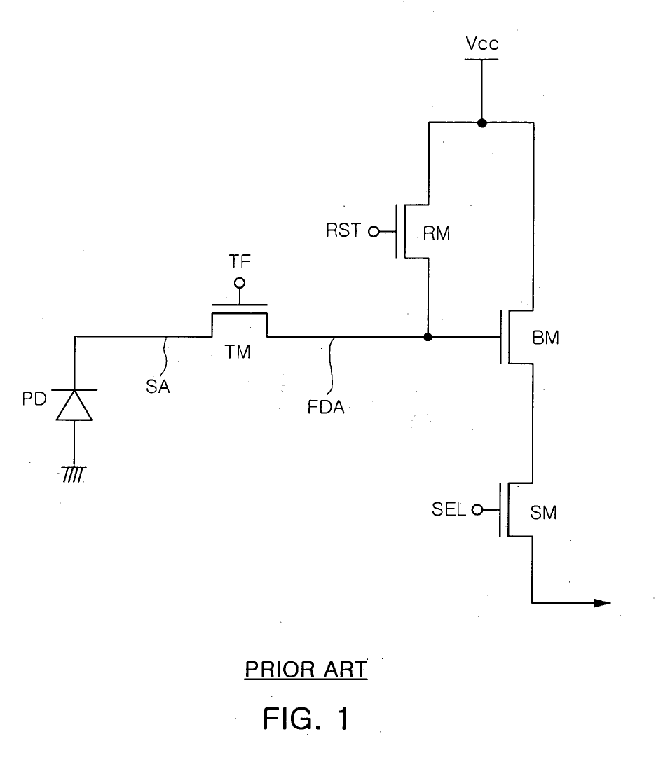

FIG. 2 is a configuration view illustrating a CMOS image sensor according to an exemplary embodiment of the invention;

FIG. 3 is a view illustrating the operation of a transmission gate unit 200 according to the embodiment of the invention; and

FIG. 4 is an equivalent circuit diagram mainly illustrating a transfer transistor according to the embodiment of the invention.

### DETAILED DESCRIPTION OF THE PREFERRED EMBODIMENT

An exemplary embodiment of the present invention will now be described in detail with reference to the accompanying drawings.

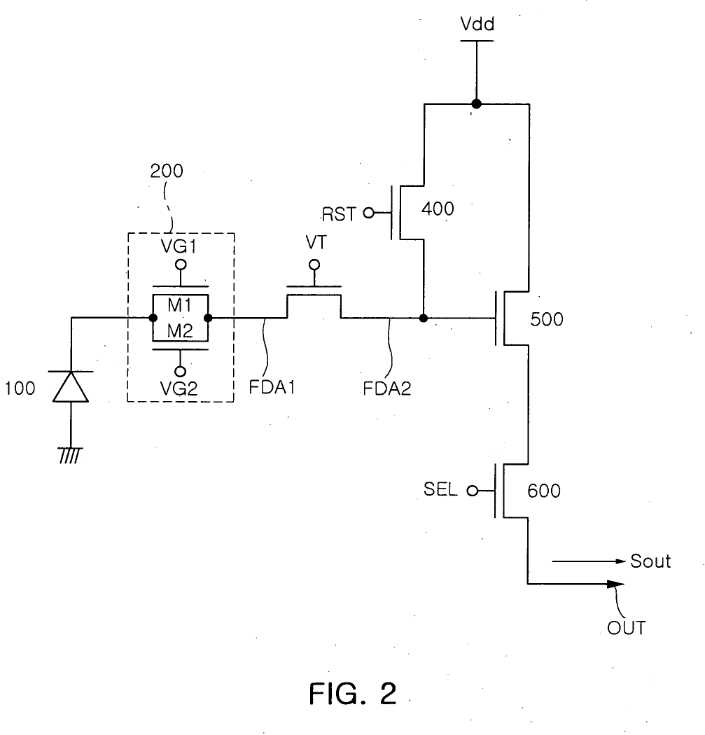

FIG. 2 is a configuration view illustrating a CMOS image sensor according to an exemplary embodiment of the invention.

Referring to FIG. 2, a CMOS image sensor according to an embodiment of the invention includes a photodiode 100, a transmission gate unit 200, a transfer transistor 300, and a drive transistor 500. The photodiode 100 receives light to generate photogenerated charges. The transmission gate unit 200 transmits the photogenerated charges, generated by the photodiode 100, to a first floating diffusion area FDA1, and increases the capacitance of the first floating diffusion area FDA1. The transfer transistor 300 transfers the photogenerated charges of the first floating diffusion area FDA1, transmitted by the transmission gate unit 200, to a second floating diffusion area FDA2. The drive transistor 500 converts the photogenerated charges of the second floating diffusion area FDA2 into a detection voltage.

Further, the CMOS image sensor according to the embodiment of the invention may also include a reset transistor 400 and a select transistor 600. The reset transistor 400 resets the photogenerated charges of the floating diffusion area FDA2. The select transistor 600 is connected between the drive transistor 500 and an output terminal OUT, and selects output of the detection voltage that is detected by the drive transistor 500.

The drive transistor 500 may be formed of a source follower transistor. The source follower transistor has a drain connected to a power supply VDD terminal, a source connected to the select transistor 600, and a gate connected to the second floating diffusion area FDA2.

The transmission gate unit 200 according to the embodiment of the invention includes an N-MOS transistor M1 and a P-MOS transistor M2. Here, the N-MOS transistor M1 has a source connected to the photodiode 100, a drain connected to the transfer transistor 300, and a gate connected to a first gate voltage VG1 terminal. The P-MOS transistor M2 has a source connected to the source of the N-MOS transistor M1, a drain connected to the drain of the N-MOS transistor M1, and a gate connected to a second gate voltage VG2 terminal.

Here, a first gate voltage VG1 is determined as a voltage that is equal to a voltage of the power supply VDD, and the second gate voltage VG2 terminal is connected to a ground terminal.

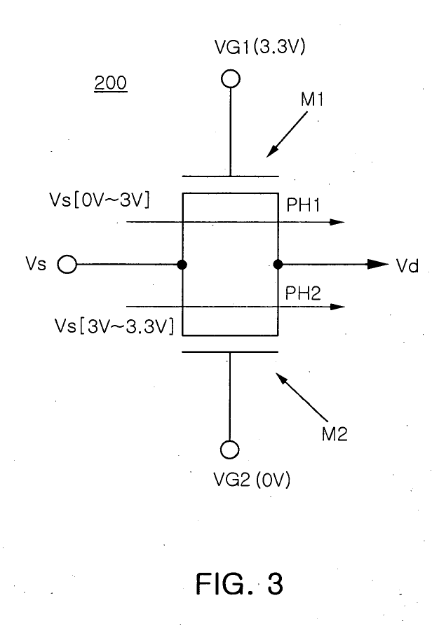

FIG. 3 is a view illustrating the operation of the transmission gate unit 200 according to the embodiment of the invention.

In FIG. 3, the N-MOS transistor M1 of the transmission gate unit 200 is turned on when a source voltage Vs by the photogenerated charges is at a low level, so as to form a first transfer path PH1, and transfers the photogenerated charges to the first floating diffusion area FDA1.

The P-MOS transistor M2 of the transmission gate unit 200 is turned on when the source voltage Vs by the photogenerated charges is at a high level, so as to form a second transfer path PH2, and transfers the photogenerated charges to the first floating diffusion area FDA1.

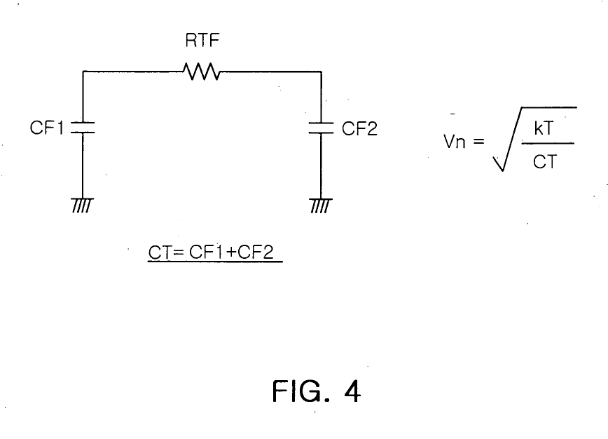

FIG. 4 is an equivalent circuit diagram mainly illustrating a transfer transistor according to the embodiment of the invention.

In FIG. 4, a resistance RTF is an equivalent resistance of the transfer transistor 300, a first capacitance CF1 is an equivalent capacitance of the first floating diffusion area FDA1, and a second capacitance CF2 is an equivalent capacitance of the second floating diffusion area FDA2.

Hereinafter, the operation and effect of the invention will be described in detail with reference to the accompanying drawings.

The CMOS image sensor according to the embodiment of the invention will be described with reference to FIGS. 2 to 4. In FIG. 2, according to the embodiment of the invention, the photodiode 100 of the CMOS image sensor receives light to generate photogenerated charges.

The generated photogenerated charges are transmitted to the first floating diffusion area FDA1 by the transmission gate unit 200. The transmission of the transmission gate unit 200 will be described with reference to FIG. 3.

The transmission gate unit 200 increases the capacitance of the first floating diffusion area FDA1 to thereby reduce thermal noise that may be included in the detection voltage by the photogenerated charges. This will be described with reference to FIG. 4.

In FIG. 2, according to the embodiment of the invention, the transfer transistor 300 transfers the photogenerated charges of the first floating diffusion area FDA1, transmitted by the transmission gate unit 200, to the second floating diffusion area FDA2.

Then, according to the embodiment of the invention, the drive transistor 500 converts the photogenerated charges of the second floating diffusion area FDA2 into the detection voltage.

For example, the drive transistor 500 may be formed of a source follower transistor. The source follower transistor has a drain connected to the power supply VDD terminal, a source connected to the select transistor 600, and a gate connected to the second floating diffusion area FDA2.

At this time, the drive transistor 500 operates in response to the voltage by the photogenerated charges of the second floating diffusion area FDA2, and outputs a voltage of the power supply VDD.

Then, according to the embodiment of the invention, the select transistor 600 is connected between the drive transistor 500 and the output terminal OUT, selects output of the detection voltage detected by the drive transistor 500, and outputs the output through the output terminal OUT.

For accurate detection, the reset transistor 400 according to the embodiment of the invention repetitively resets the photogenerated charges of the second floating diffusion area FDA2 between periodic detection intervals according to a reset signal RST.

Referring to FIG. 2, the transmission gate unit 200 according to the embodiment of the invention will be described.

The transmission gate unit 200 includes the N-MOS transistor M1 and the P-MOS transistor M2. The N-MOS transistor M1 includes the source connected to the photodiode 100, the drain connected to the transfer transistor 300, and the gate connected to the first gate voltage VG1 terminal. The P-MOS transistor M2 includes the source connected to the source of the N-MOS transistor M1, the drain connected to the drain of the N-MOS transistor M1, and the gate connected to the second gate voltage VG2 terminal.

At this time, the first gate voltage VG1 is determined as a voltage that is equal to a voltage of the power supply VDD, and the second gate voltage VG2 terminal is connected to the ground terminal. For example, when the voltage of the power supply VDD is 3.3V, a first gate voltage VG1 may also be 3.3V. Here, the second gate voltage VG2 has a ground level.

Hereinafter, the transmission of the transmission gate unit 200 according to the embodiment of the invention will be described.

In FIG. 3, when the first gate voltage VG1 is 3.3V, and a threshold voltage of the N-MOS transistor M1 of the transmission gate unit 200 is 0.3V, the N-MOS transistor M1 of the transmission gate unit 200 is turned on if the source voltage Vs by the photogenerated charges is less than 3V, that is, if the source voltage Vs is between 0V and 3V, so as to form the first transfer path PH1. The photogenerated charges generated by the photodiode 100 are transferred to the first floating diffusion area FDA1 through the first transfer path PH1.

The P-MOS transistor M2 of the transmission gate unit 200 is turned on when the source voltage Vs by the photogenerated charges is between 3V and 3.3V, so as to form the second transfer path PH2. The photogenerated charges that are generated by the photodiode 100 are transmitted to the first floating diffusion area FDA1 through the second transfer path PH2.

Therefore, according to the embodiment of the invention, an input voltage range of the transmission gate unit 200 is extended from approximately 0V to the first gate voltage VG1, that is, 3.3V.

Hereinafter, thermal noise reduction will be described with reference to the equivalent circuit diagram mainly illustrating the transfer transistor according to the embodiment of the invention.

In FIG. 4, the resistance RTF is the equivalent resistance of the transfer transistor 300, the first capacitance CF1 is the equivalent capacitance of the first floating diffusion area FDA1, and the second capacitance CF2 is the equivalent capacitance of the second floating diffusion area FDA2.

Here, in the CMOS image sensor according to the embodiment of the invention, a thermal noise voltage Vn may be determined by the following equation:

$$Vn = \sqrt{\frac{kT}{CT}} , \qquad Equation 1$$

where k is a constant, T is temperature, and CT is total capacitance.

Here, as shown in FIG. 4, the first capacitance CF1 and the second capacitance CF2 are connected in parallel with each other with the resistance RTF located therebetween. The total capacitance CT is the sum of the first capacitance CF1 and the second capacitance CF2.

Therefore, the first capacitance CF1 is increased by the transmission gate unit 200, and the total capacitance CT is correspondingly increased. As a result, the thermal noise is reduced by the transmission gate unit 200.

In an image sensor that is used when performing video communication and storing video, a screen may freeze due to a decrease in number of frames when it is dark. In order to prevent this, the CMOS image sensor according to the embodiment of the invention reduces ‘kTc’ noise corresponding to thermal noise to thereby maintain high sensitivity even at low levels of luminance. That is, since the decrease in number of frames can be prevented even in dark places, video data having high quality can be achieved.

Further, the transmission gate unit includes the N-MOS transistor and the P-MOS transistor to extend an operating range of the transmission gate unit with respect to the input voltage. At the same time, the capacitance of the floating diffusion area is increased to thereby reduce the thermal noise.

As set forth above, according to the exemplary embodiment of the invention, high sensitivity can be maintained even at low levels of luminance by reducing thermal noise, and an input voltage range can be extended to a gate voltage.

While the present invention has been shown and described in connection with the exemplary embodiment, it will be apparent to those skilled in the art that modifications and variations can be made without departing from the spirit and scope of the invention as defined by the appended claims.

What is claimed is:

1. A CMOS image sensor comprising:
a photodiode receiving light to generate photogenerated charges;
a transmission gate unit transmitting the photogenerated charges generated by the photodiode to a first floating diffusion area, and increasing the capacitance of the first floating diffusion area;
a transfer transistor transferring the photogenerated charges of the first floating diffusion area transmitted by the transmission gate unit to a second floating diffusion area; and
a drive transistor converting the photogenerated charges of the second floating diffusion area into a detection voltage.

2. The CMOS image sensor of claim 1, further comprising a reset transistor resetting the photogenerated charges of the second floating diffusion area.

3. The CMOS image sensor of claim 2, further comprising a select transistor connected between the drive transistor and an output terminal, and selecting output of the detection voltage detected by the drive transistor.

4. The CMOS image sensor of claim 3, wherein the drive transistor is a source follower transistor having a drain connected to a power supply, a source connected to the select transistor, and a gate connected to the second floating diffusion area.

5. The CMOS image sensor of claim 4, wherein the transmission gate unit comprises:
an N-MOS transistor having a source connected to the photodiode, a drain connected to the transfer transistor, and a gate connected to a first gate voltage terminal; and
a P-MOS transistor having a source connected to the source of the N-MOS transistor, a drain connected to the drain of the N-MOS transistor, and a gate connected to a second gate voltage terminal.

6. The CMOS image sensor of claim 5, wherein a first gate voltage is equal to a voltage of the power supply.

7. The CMOS image sensor of claim 5, wherein the second gate voltage terminal is connected to a ground terminal.
